(19) United States
(12) Patent Application Publication
(10) Pub. No.: US 2024/0233846 A9
(43) Pub. Date: Jul. 11, 2024

(54) SEMICONDUCTOR DEVICE AND VOLTAGE APPLICATION METHOD

(71) Applicant: Rohm Co., Ltd., Kyoto (JP)

(72) Inventor: Katsuhiko Onishi, Kyoto (JP)

(21) Appl. No.: 18/534,498

(22) Filed: Dec. 8, 2023

Related U.S. Application Data
(63) Continuation of application No. PCT/JP2022/019926, filed on May 11, 2022.

(30) Foreign Application Priority Data
Jun. 10, 2021 (JP) 2021-097420

(51) Int. Cl. G11C 17/18; G11C 5/14

(52) U.S. Cl. CPC G11C 17/18; G11C 5/147

(57) ABSTRACT

A semiconductor device includes, for example: an internal power supply that generates VREG from VIN; a circuit block that operates from VREG; a circuit block that operates from a node voltage Vn appearing at an internal node n1; and a switcher that switches the connection destination of the internal node n1. The switcher includes: a switch SW1 connected between an application terminal for VREG and the internal node n1; and a switch SW2 connected between an external terminal PAD and the internal node n1. The circuit block includes a switch controller configured to control the switches SW1 and SW2. The switch controller controls the switcher such that switching between a first state (SW1 on, SW2 off) and a second state (SW1 off, SW2 on) proceeds via a third state (SW1 on, SW2 on).

### CROSS-REFERENCE TO RELATED APPLICATIONS

This nonprovisional application is a continuation application of International Patent Application No. PCT/JP2022/019926 filed on May 11, 2022, which claims priority Japanese Patent Application No. 2021-097420 filed on Jun. 10, 2021, the entire contents of which are hereby incorporated by reference.

### TECHNICAL FIELD

The invention disclosed herein relates to semiconductor devices and methods of applying a voltage.

### BACKGROUND ART

Some known semiconductor devices are capable of changing the functions of a terminal according to their operating mode.

One example of known technology related to what has just been mentioned is seen in Patent Document 1 identified below.

### CITATION LIST

### Patent Literature

Patent Document 1: JP-A-2000-150482 (e.g., paragraphs 0013, 0016-0017, 0026, and 0043-0045; FIGS. 1, 2, and 13)

### BRIEF DESCRIPTION OF DRAWINGS

FIG. 1 is a diagram showing a semiconductor device of a first comparative example.

FIG. 2 is a diagram showing a semiconductor device of a second comparative example.

FIG. 3 is a diagram showing a semiconductor device of a third comparative example.

FIG. 4 is a diagram showing a semiconductor device according to a first embodiment.

FIG. 5 is a diagram showing an operation sequence according to the first embodiment.

FIG. 6 is a diagram showing one example of a method of sharing a pad.

FIG. 7 is a diagram showing a semiconductor device according to a second embodiment.

### DESCRIPTION OF EMBODIMENTS

### First Comparative Example

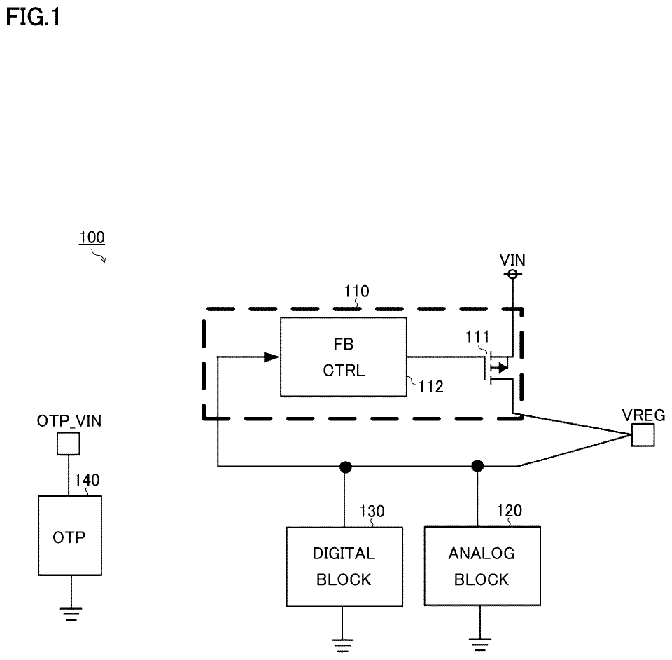

FIG. 1 is a diagram showing a semiconductor device of a first comparative example (an example of circuit configuration to be compared with the embodiments described later). The semiconductor device 100 of the first comparison example includes an internal power supply 110, an analog circuit block 120, a digital circuit block 130, and an OTP (one-time programmable) memory 140.

The internal power supply 110 is a linear regulator that generates from an input voltage VIN (e.g., 3.3 V) a predetermined internal supply voltage VREG (e.g., 1.5 V), and includes, for example, an output transistor 111 and a feedback controller 112.

The output transistor 111 is connected between an application terminal for the input voltage VIN and an application terminal for the internal supply voltage VREG, and its conductance (hence its on-resistance value) is controlled linearly according to a control signal output from the feedback controller 112. The output transistor 111 can be implemented suitably with, for example, a P-channel MOSFET (metal-oxide-semiconductor field-effect transistor).

The feedback controller 112 receives a feedback of the internal supply voltage VREG (or a division voltage of it), and generates a control signal (i.e., gate signal) for controlling the output transistor 111 such that the internal supply voltage VREG is equal to a target value.

The analog circuit block 120 and the digital circuit block 130 each operate by being supplied with the internal supply voltage VREG.

The OTP memory 140 is a non-volatile semiconductor storage device to which data can be written only once. Note that an OTP memory 140 requires different driving voltages to operate during a data writing period and during a data non-writing period (including a data reading period). For example, while the driving voltage required during the data reading period is 1.5 V, which is equal to the internal supply voltage VREG, the driving voltage required during the data writing period is 5 V. Accordingly, the semiconductor device 100 incorporating the OTP memory 140 has to be provided separately with an external power terminal for receiving an OTP supply voltage OTP_VIN for the sole purpose of data write operation that is performed only once.

One method to shrink the mounting area of the semiconductor device 100 by doing without a separate external power terminal is to raise the withstand voltages of the analog circuit block 120 and the digital circuit block 130 so that the internal supply voltage VREG can be raised to the 5 V. However, increasing the withstand voltages of the analog circuit block 120 and the digital circuit block 130 leads to increases in their respective circuit areas.

### Second Comparative Example

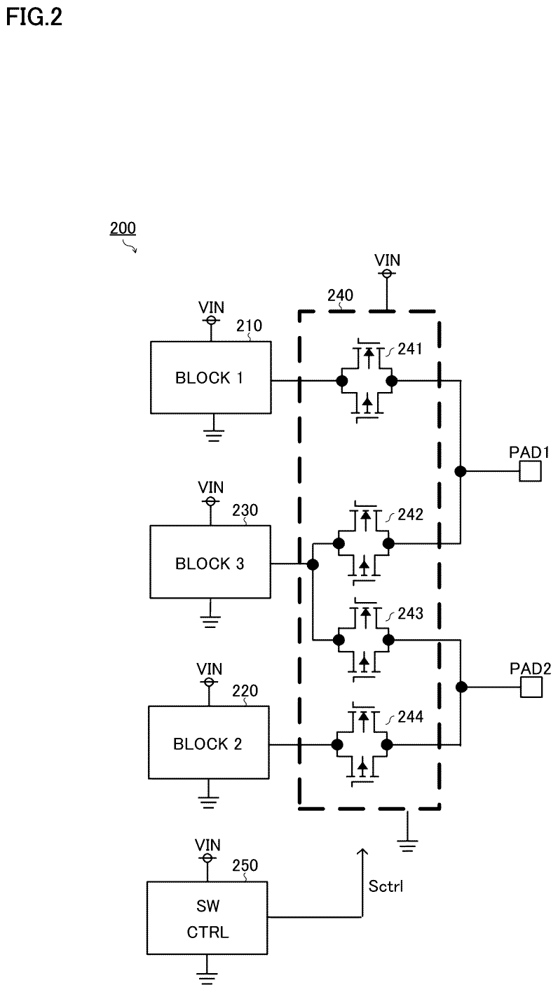

FIG. 2 is a diagram showing a semiconductor device of a second comparative example (an example of circuit configuration to be compared with the embodiments described later). The semiconductor device 200 of the second comparison example includes circuit blocks 210, 220, and 230, a switcher 240, a and switch controller 250.

The circuit blocks 210, 220, and 230 each operate by being supplied with the input voltage VIN.

The switcher 240 operates by being supplied with the input voltage VIN, and switches the connection paths among the circuit blocks 210, 220, and 230 and pads PAD1 and PAD2 according to a switch control signal Sctrl output from the switch controller 250. The switcher 240 includes, for example, an analog switch 241 connected between the circuit block 210 and the pad PAD1, an analog switch 242 connected between the circuit block 230 and the pad PAD1, an analog switch 243 connected between the circuit block 230 and the pad PAD2, and an analog switch 244 connected between the circuit block 220 and the pad PAD2.

The switch controller 250 operates by being supplied with the input voltage VIN, and generates the switch control signal Sctrl in such a way that the two pads PAD1 and PAD2 are shared among the three circuit blocks 210, 220, and 230.

Switching circuit blocks connected to external terminals by using analog switches with a view to reducing the number of external terminals as described above is known and practiced.

### Third Comparative Example

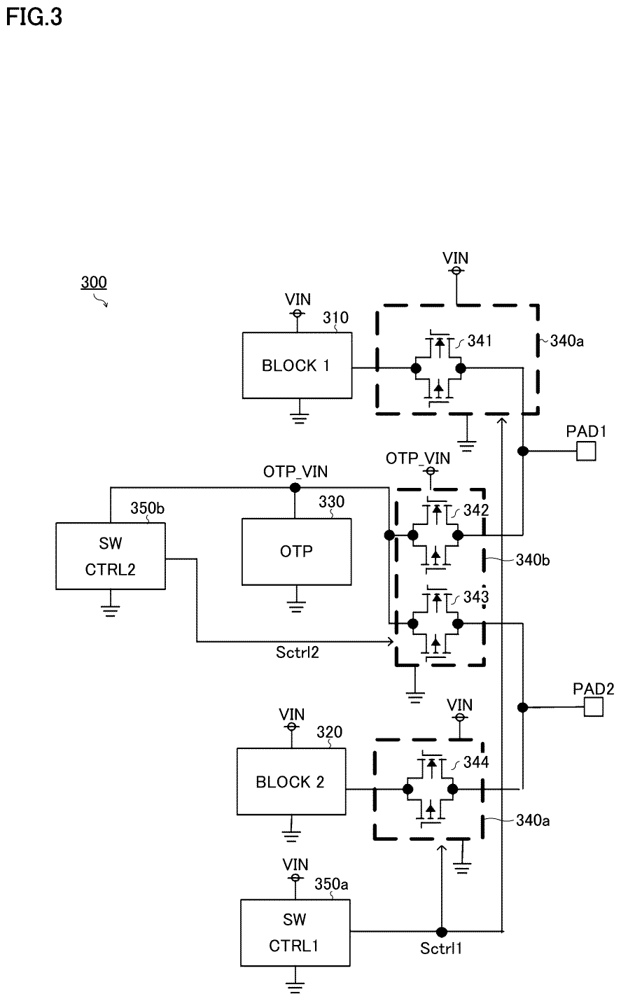

FIG. 3 is a diagram showing a semiconductor device of a third comparative example (an example of circuit configuration to be compared with the embodiments described later). The semiconductor device 300 of the third comparison example includes circuit blocks 310 and 320, an OTP memory 330, switchers 340a and 340b, and switch controllers 350a and 350b.

The circuit blocks 310 and 320 each operate by being supplied with the input voltage VIN.

The OTP memory 330 is a non-volatile semiconductor storage device to which data can be written only once, and requires different driving voltages to operate during a data writing period and during a data non-writing period (including a data reading period). The switcher 340a operates by being supplied with the input voltage VIN, and switches the connection paths among the circuit blocks 310 and 320 and pads PAD1 and PAD2 according to a switch control signal Sctrl1 output from the switch controller 350a. The switcher 340a includes, for example, an analog switch 341 connected between the circuit block 310 and the pad PAD1 and an analog switch 344 connected between the circuit block 320 and the pad PAD2.

The switcher 340b operates by being supplied with the OTP supply voltage OTP_VIN, and switches the connection paths among the OTP memory 330, the switch controller 350b, and the pads PAD1 and PAD2 according to a switch control signal Sctrl2 output from the switch controller 350b. The switcher 340b includes, for example, an analog switch 342 connected between, at one end, the OTP memory 330 and the switch controller 350b and, at the other, the pad PAD1 and an analog switch 343 connected between, at one end, the OTP memory 330 and the switch controller 350b and, at the other, the pad PAD2.

The switch controller 350a operates by being supplied with the input voltage VIN, and generates the switch control signal Sctrl1 in such a way that the two pads PAD1 and PAD2 are shared among the circuit blocks 310 and 320 and the OTP memory 330.

The switch controller 350b operates by being supplied with the OTP supply voltage OTP_VIN, and generates the switch control signal Sctrl2 in such a way that the two pads PAD1 and PAD2 are shared among the circuit blocks 310 and 320 and the OTP memory 330.

With a configuration as described above where the OTP memory 330 and the switch controller 350b are supplied from a common power supply, it is difficult for the switch controller 350b to control the switching by the switcher 340b. Consider, for example, a situation where electric power is being supplied from the pad PAD1 via the analog switch 342. From this state, turning the analog switch 342 off and then turning the analog switch 343 on with the intention of switching to the supply of electric power from the pad PAD2 results in, when the analog switch 342 is turned off, shutting off the supply of electric power to the switch controller 350b; this makes it impossible to control the switcher 340b properly.

Presented below will be novel embodiments free from the shortcomings mentioned above.

### First Embodiment

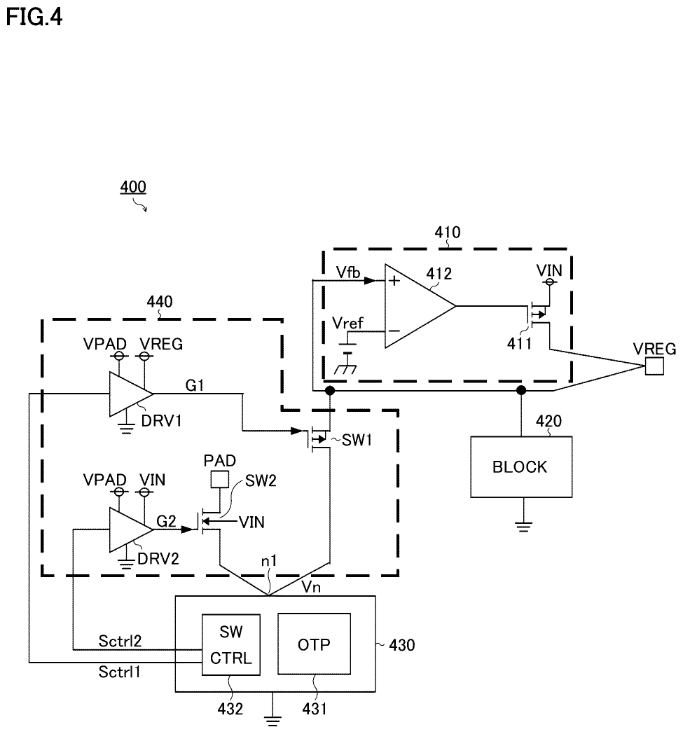

FIG. 4 is a diagram showing a semiconductor device according to a first embodiment. The semiconductor device 400 of the first embodiment includes an internal power supply 410, a first circuit block 420, a second circuit block 430, and a switcher 440.

The internal power supply 410 is a linear regulator that generates from an input voltage VIN (e.g., 3.3 V) a predetermined internal supply voltage VREG (e.g., 1.5 V), and includes, for example, an output transistor 411 and an operational amplifier 412.

The output transistor 411 is connected between an application terminal for the input voltage VIN and an application terminal for the internal supply voltage VREG, and its conductance (hence its on-resistance value) is controlled linearly according to a control signal output from the operational amplifier 412. The output transistor 411 can be implemented suitably with, for example, a P-channel MOSFET.

The operational amplifier 412 generates a control signal (i.e., gate signal) that controls the output transistor 111 such that a feedback voltage Vfb (e.g., the internal supply voltage VREG itself or a division voltage of it), which is fed to the non-inverting input terminal (+) of the operational amplifier 412, is equal to (is imaginarily short-circuited to) a reference voltage Vref, which is fed to the inverting input terminal (—) of the operational amplifier 412. While the diagram shows as a feedback controller for the internal power supply 410 the simplest configuration implemented with an operational amplifier 412, the feedback controller can have any topology. Or, for example, the operational amplifier 412 may include, in a differential output stage, an offset canceller so that the input offset of the operational amplifier 412 does not have temperature dependence.

It is preferable that, as in the linear regulator shown in the diagram, the internal power supply 410 be one that only has a capacity (current source capacity) to supply a current to the application terminal for the internal supply voltage VREG. The reason will be discussed in detail later.

The first circuit block 420 operates by being supplied with the internal supply voltage VREG. The first circuit block 420 can be, for example, an analog circuit block.

The second circuit block 430 operates by being supplied with a node voltage Vn that appears at an internal node n1. The second circuit block 430 can be, for example, a digital circuit block. In terms of what is shown in the diagram, the second circuit block 430 includes an OTP memory 431 and a switch controller 432.

The OTP memory 431 is a non-volatile semiconductor storage device to which data can be written only once. Note that an OTP memory 431 requires different driving voltages to operate during a data writing period and during a data non-writing period (including a data reading period). For example, while the driving voltage required during the data reading period is 1.5 V, which is equal to the internal supply voltage VREG, the driving voltage required during the data writing period is 5 V.

As described above, the second circuit block 430 includes the OTP memory 431 as one example of a load circuit that requires different driving voltages in different operating modes. Including the OTP memory 431, the semiconductor device 400 can switch its functions according to the data written to the OTP memory 431. More specifically, at the time of the shipment of the semiconductor device 400, desired data (e.g., data “0” for models intended for one use and data “1” for models intended for another use) can be written to the OTP memory 431 to develop from a single semiconductor device 400 a lineup of a plurality of models adapted to a plurality of uses respectively.

The switch controller 432 operates by being supplied with the node voltage Vn, and generates switch control signals Sctrl1 and Sctrl2 for the switcher 440 such that the connection destination of the internal node n1 can be switched without suspension of the supply of the node voltage Vn. The operation of the switch controller 432 for controlling the switcher 440 (the operation for turning on and off switches SW1 and SW2, which will be described later) will be described in detail later.

The switcher 440 is a circuit block configured to switch the connection destination of the internal node n1 based on the switch control signals Sctrl1 and Sctrl2 fed from the switch controller 432. The switcher 440 includes switches SW1 and SW2 and drivers DRV1 and DRV2.

The switch SW1 is connected between an application terminal for the internal supply voltage VREG and the internal node n1, and is turned on and off based on a gate signal G1 output from the driver DRV1. In the diagram, the switch SW1 is implemented with a P-channel MOSFET. The source and the back gate of the switch SW1 are connected to the application terminal for the internal supply voltage VREG. The drain of the switch SW1 is connected to the internal node n1. The gate of the switch SW1 is connected to the output terminal of the driver DRV1. Accordingly, when the gate signal G1 is at low level (GND), the switch SW1 is on and thus the path between the internal supply voltage VREG and the internal node n1 conducts; when the gate signal G1 is at high level (VERG or VPAD), the switch SW1 is off and thus the path between the application terminal for the internal supply voltage VREG and the internal node n1 is cut off. Incidentally, the switch SW1 may instead be implemented with an analog switch having a P-channel MOSFET and an N-channel MOSFET connected in parallel.

The switch SW2 is connected between a pad PAD (an external terminal to which an external supply voltage VPAD is applied) and the internal node n1, and is turned on and off based on a gate signal G2 output from the driver DRV2. In the diagram, the switch SW2 is implemented with an N-channel MOSFET. The drain of the switch SW2 is connected to the pad PAD. The source of the switch SW2 is connected to the internal node n1. The back gate of the switch SW2 is connected to an application terminal for the input voltage VIN. The gate of the switch SW2 is connected to the output terminal of the driver DRV2. Accordingly, when the gate signal G2 is at high level (VIN or VPAD), the switch SW2 is on and thus the path between the pad PAD and the internal node n1 conducts; when the gate signal G2 is at low level (GND), the switch SW2 is off and thus the path between the pad PAD and the internal node n1 is cut off. The switch SW2 may be implemented with, instead of an N-channel MOSFET, a P-channel MOSFET, or with an analog switch having a P-channel MOSFET and an N-channel MOSFET connected in parallel.

The pad PAD need not be a dedicated pad provided to receive the external supply voltage VPAD; instead, an existing pad that is used for another purpose during an ordinary operation period (including a data reading period) in which no writing of data to the OTP memory 431 takes place can be shared. A method of sharing the pad PAD will be described later.

The driver DRV1 operates by being supplied with the internal supply voltage VREG or the external supply voltage VPAD, and generates the gate signal G1 according to the switch control signal Sctrl1.

The driver DRV2 operates by being supplied with the input voltage VIN or the external supply voltage VPAD, and generates the gate signal G2 according to the switch control signal Sctrl2.

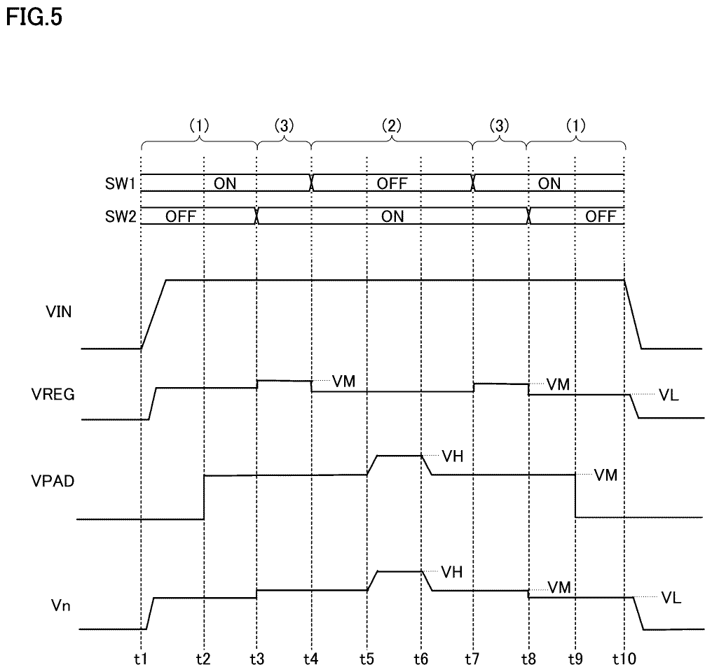

FIG. 5 is a timing chart showing the operation sequence according to the first embodiment (in particular, during a data writing period with respect to the OTP memory 431, i.e., a period in which data is written to the OTP memory 431), depicting, from top down, the on/off states of the switches SW1 and SW2, the input voltage VIN, the internal supply voltage VREG, the external supply voltage VPAD, and the node voltage Vn.

The following description of the operation sequence assumes that, over a period from time point t1 to time point t10, the semiconductor device 400 is supplied with the input voltage VIN (e.g., 3.3 V) with feedback control acting so as to keep the internal supply voltage VREG at a target value VL (e.g., 1.5 V).

The operating state of the switcher 440 switches among a first state (1), a second state (2), and a third state (3). In the first state (1), the switch SW1 is on and the switch SW2 is off. In the second state (2), the switch SW1 is off and the switch SW2 is on. In the second state (3), the switches SW1 and SW2 are both on.

Between time points t1 and t3, the switcher 440 is in the first state (1). That is, during this period, the path between the internal node n1 and the application terminal for the internal supply voltage VREG conducts, and the path between the internal node n1 and the pad PAD is cut off. Thus, Vn=VREG (=VL).

Note that, at time point t2, before a switch from the first state (1) to the third state (3), the external supply voltage VPAD is set to a first voltage VM that is equal to or higher than the target value VL of the internal supply voltage VREG. At this time point, however, with the path between the internal node n1 and the pad PAD cut off, Vn=VREG (=VL)≠VPAD.

The first voltage VM mentioned above should ideally be set to a voltage value that is equal to the output value of the internal supply voltage VREG at time point t2. However, if due to variation or fluctuation of the first voltage VM and the internal supply voltage VREG the first voltage VM is lower than the internal supply voltage VREG, a current unnecessarily passes from the application terminal for the internal supply voltage VREG to the pad PAD. To avoid that, it is preferable that the first voltage VM be set to a voltage value (e.g., 1.6 V) slightly higher than the target value VL (e.g., 1.5 V) of the internal supply voltage VREG.

Between time points t3 and t4, the switcher 440 is in the third state (3). That is, during this period, the internal node n1 stays connected to both the application terminal for the internal supply voltage VREG and the pad PAD. Note that, as mentioned above, before a switch from the first state (1) to the third state (3), the pad PAD is fed with the first voltage VM (≥VL) as the external supply voltage VPAD.

Here, the internal power supply 410 only has a capacity (current source capacity) to feed a current to the application terminal for the internal supply voltage VREG, and has no capacity (current sink capacity) to draw a current from the application terminal for the internal supply voltage VREG. Accordingly, even if VPAD>VREG, the internal supply voltage VREG rises until it becomes equal to the external supply voltage VPAD without causing an overcurrent. That is, in the third state (3), Vn=VREG=VPAD (=VM).

In a situation where it is possible, in the third state (3) described above, to apply an external supply voltage VPAD with a value equal to the internal supply voltage VREG to the pad PAD, the internal power supply 410 may be implemented with a type that has both a current source capacity and a current sink capacity.

Between time points t4 and t7, the switcher 440 is in the second state (2). That is, during this period, the path between the internal node n1 and the application terminal for the internal supply voltage VREG is cut off and the path between the internal node n1 and the pad PAD conducts. Accordingly, with the node voltage Vn kept at the external supply voltage VPAD, the internal supply voltage VREG returns to the target value VL.

While the switcher 440 is in the second state (2), the external supply voltage VPAD is set to a second voltage VH (e.g., 5 V as needed during the data writing period with respect to the OTP memory 431). More specifically, at time point t5, after a switch from the third state (3) to the second state (2), the external supply voltage VPAD is raised from the first voltage VM to the second voltage VH; at time point t6, before a switch from the second state (2) to the third state (3), the external supply voltage VPAD is dropped from the second voltage VH to the first voltage VM. Accordingly, between time points t5 to t6, Vn=VPAD=VH, and thus data can be written to the OTP memory 431.

Between time points t7 and t8, the switcher 440 is back in the third state (3). That is, during this period, the internal node n1 stays connected to both the application terminal for the internal supply voltage VREG and the pad PAD. As mentioned above, before a switch from the second state (2) to the third state (3), the pad PAD is fed with the first voltage VM (>VL) as the external supply voltage VPAD. Accordingly, in the third state (3), Vn=VREG=VPAD (=VM).

Between time points t8 and t10, the switcher 440 is in the first state (1). That is, during this period, the path between the internal node n1 and the application terminal for the internal supply voltage VREG conducts and the path between the internal node n1 and the pad PAD is cut off. Accordingly, Vn=VREG (=VL).

Note that, at time point t9, after a switch from the third state (3) to the first state (1), the application of the external supply voltage VPAD is stopped. At this time point, however, with the path between the internal node n1 and the pad PAD cut off, the node voltage Vn is kept at the internal supply voltage VREG (=VL).

As described above, in the semiconductor device 400 of the first embodiment, the switch controller 432 keeps the switcher 440 in the second state (2) during the data writing period with respect to the OTP memory 431 and keeps the switcher 440 in the first state (1) otherwise, that is, during the data non-writing period (including the data reading period) with respect to the OTP memory 431.

Particularly to be noted here is that the switch controller 432 controls the semiconductor device 400 such that a transition between the first state (1) and the second state (2) proceeds via the third state (3), in which the switches SW1 and SW2 are both on. That is, when the node voltage Vn is switched between the internal supply voltage VREG and the external supply voltage VPAD, a period occurs in which the switches SW1 and SW2 are simultaneously on.

Moreover, as mentioned previously, the internal power supply 410 only has a current source capacity. Accordingly, in the third state (3), in which the switches SW1 and SW2 are simultaneously on, even if an external supply voltage VPAD slightly higher than the internal supply voltage VREG is applied to the pad PAD, no overcurrent passes from the pad PAD to the application terminal for the internal supply voltage VREG. Thus, the semiconductor device 400 of the first embodiment, by giving the internal power supply 410 only a current source capacity, achieves a configuration where the switches SW1 and SW2 can be simultaneously on (in other words, a configuration where the switches SW1 and SW2 being simultaneously on does not cause a problem).

With the configuration described above, at least one of the application terminal for the internal supply voltage VREG and the pad PAD conducts to the internal node n1 at any time, and thus a switch between the internal supply voltage VREG and the external supply voltage VPAD does not cause a drop in the node voltage Vn. Accordingly, the switch controller 432 can continue being fed with the node voltage Vn all the time, and this makes it possible to control the switcher 440 without any problem.

In addition, with the semiconductor device 400 of the first embodiment, as mentioned previously, no dedicated pad is provided but an existing pad PAD is shared as the external terminal for receiving the external supply voltage VPAD. That is, the existing pad PAD can be assigned the function as an external power terminal only during the data writing period with respect to the OTP memory 431 and, during the data non-writing period (including the data reading period) with respect to the OTP memory 431, the path between the internal node n1 and the application terminal for the internal supply voltage VREG can be left short-circuited.

With this configuration, permitting a single external terminal (pad PAD) to have a plurality of functions eliminates the need to separately provide an external power terminal that is not used other than at factory shipment or on other particular occasions. This helps shrink the mounting area of the semiconductor device 400.

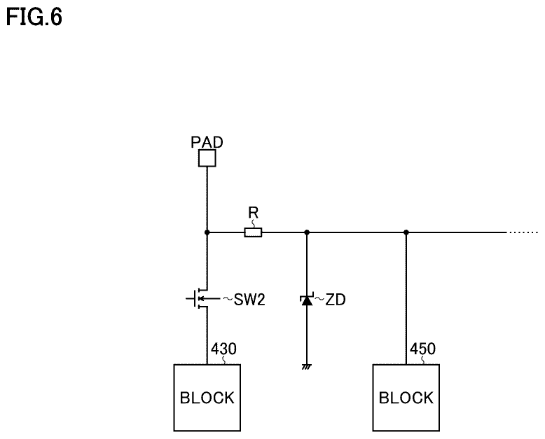

FIG. 6 is a diagram showing one example of a method of sharing a pad. In a case where an existing pad is shared as a pad PAD for receiving the external supply voltage VPAD during the data writing period with respect to the OTP memory 431, basically it is necessary to raise the withstand voltage of a third circuit block 450 that is connected to that pad. Accordingly, of existing pads, any that is connected to a large-scale circuit block or that is connected to a number of circuits blocks should better be avoided as a pad PAD for receiving the external supply voltage VPAD during the data writing period with respect to the OTP memory 431.

One example of an external terminal suitable to be shared as the pad PAD described above is an enable pad that is fed with an enable signal for controlling whether to enable or disable the semiconductor device 400. For example, in a case where the enable pad is shared as the pad PAD described above, whether to enable or disable the semiconductor device 400 is switched according to the enable signal that is fed to the pad PAD when the switcher 440 is in the first state (1) mentioned above.

Generally, an enable signal is a binary signal that, when the semiconductor device 400 is started up, simply switches from a logic level for a disabled state (e.g., low level) to a logic level for an enabled state (e.g., high level), and is not required to have fast response.

Accordingly, in a case where an enable pad is shared as the pad PAD described above, it is possible to provided a resistor R for limiting the current passing from the pad PAD to the third circuit block 450 or to provide a clamper (e.g., a Zener diode ZD) for limiting the voltage applied from the pad PAD to the third circuit block 450 downstream of the resistor R. This eliminates the need to unnecessarily raise the withstand voltage of the third circuit block 450, and thus helps minimize an increase in the circuit area.

The above measure of providing a resistor R for limiting a current is unfeasible in a case where the third circuit block 450 is a circuit block that consumes a high current. This is because a high current passing through the third circuit block 450 produces a high voltage drop across the resistor R, resulting in a drop in the supply voltage to the third circuit block 450.

In view of this, in a case where an existing pad is shared as a pad PAD for receiving the external supply voltage VPAD during the data writing period with respect to the OTP memory 431, it is preferable to avoid a pad that is connected to a circuit block that consumes a high current.

### Second Embodiment

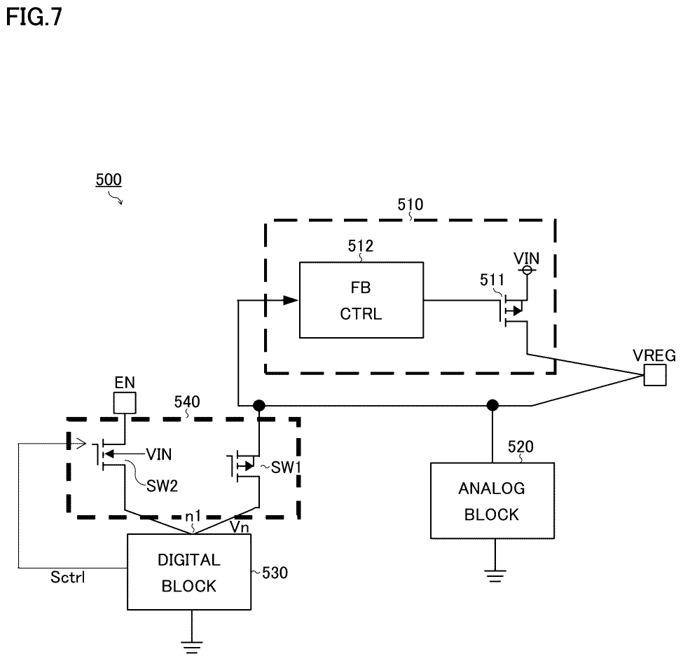

FIG. 7 is a diagram showing a semiconductor device according to a second embodiment. The semiconductor device 500 shown there includes an internal power supply 510, an analog circuit block 520, a digital circuit block 530, and a switcher 540.

The internal power supply 510 is a linear regulator that generates from an input voltage VIN (e.g., 3.3 V) a predetermined internal supply voltage VREG (e.g., 1.5 V), and includes, for example, an output transistor 511 and a feedback controller 512.

The output transistor 511 is connected between an application terminal for the input voltage VIN and an application terminal for the internal supply voltage VREG, and its conductance (hence its on-resistance value) is controlled linearly according to a control signal output from the feedback controller 512. The output transistor 511 can be implemented suitably with, for example, a P-channel MOSFET (metal-oxide-semiconductor field-effect transistor).

The feedback controller 512 receives a feedback of the internal supply voltage VREG (or a division voltage of it), and generates a control signal (i.e., gate signal) for controlling the output transistor 511 such that the internal supply voltage VREG is equal to a target value.

The analog circuit block 520 operates by being supplied with the internal supply voltage VREG.

The digital circuit block 530 operates by being supplied with a node voltage Vn that appears at an internal node n1. Note that the digital circuit block 530 is a target on which to execute quiescent supply current testing (what is called IDDQ [quiescent supply current] testing or measurement). The digital circuit block 530 also has a function as a switch controller that generates a switch control signal Sctrl for the switcher 540 such that the connection destination of the internal node n1 can be switched without suspension of the supply of the node voltage Vn.

The switcher 540 is a circuit block configured to switch the connection destination of the internal node n1 based on the switch control signal Sctrl output from the digital circuit block 530, and includes switches SW1 and SW2. Though not expressly shown in the diagram, the switcher 540 may include, as components of it, drivers DRV1 and DRV2 as shown in FIG. 4.

The switch SW1 is connected between an application terminal for the internal supply voltage VREG and the internal node n1. In the diagram, the switch SW1 is implemented with a P-channel MOSFET. Instead, the switch SW1 may be implemented with an analog switch having a P-channel MOSFET and an N-channel MOSFET connected in parallel.

The switch SW2 is connected between an enable pad EN and the internal node n1. The enable pad EN is one example of an existing pad that, during an IDDQ testing non-execution period (i.e., a period in which no IDDQ testing is being performed), functions as an input terminal for an enable signal and that, during an IDDQ testing execution period (i.e., a period in which IDDQ testing is being performed), doubles as an external power terminal fed with the external supply voltage VPAD (e.g., 2 V) and a sense terminal for sensing a quiescent supply current that passes through the digital circuit block 530.

The switch SW2 can be suitably implemented not with a P-channel MOSFET but with an N-channel MOSFET. If, for the sake of discussion, the switch SW2 is implemented with a P-channel MOSFET, a logic holding resistor for reliably keeping the switch SW2 off during the IDDQ testing non-execution period needs to be inserted between the gate and the source of the switch SW2. This inconveniently results in, during the IDDQ testing execution period, a current passing through the logic holding resistor; this makes it impossible to properly sense the quiescent supply current in the digital circuit block 530. By contrast, implementing the switch SW2 with an N-channel MOSFET eliminates the need for the logic holding resistor mentioned above, and makes it possible to execute IDDQ testing properly.

In the semiconductor device 500 of this embodiment, basically, the digital circuit block 530 keeps the switcher 540 in the previously mentioned first state (1) (SW1 on, SW2 off) during the IDDQ testing non-execution period and in the second state (2) (SW1 off and SW2 on) during the IDDQ testing execution period. Particularly to be noted here is that the digital circuit block 530 controls the switcher 540 such that a transition between the first state (1) and the second state (2) proceeds via the third state (3), in which the switches SW1 and SW2 are both on. In addition, the semiconductor device 500, by giving the internal power supply 510 only a current source capacity, achieves a configuration where the switches SW1 and SW2 can be simultaneously on. The operation sequence according to the second embodiment (in particular, during the IDDQ testing execution period) is similar to that shown in FIG. 5 and described previously, and therefore no overlapping description will be repeated.

With the configuration described above, the digital circuit block 530 can continue being fed with the node voltage Vn all the time, and thus can control the switcher 540 without any problem even when a switch takes place between the internal supply voltage VREG and the external supply voltage VPAD.

Moreover, with the semiconductor device 500 of the second embodiment, an existing enable pad EN is shared as an external terminal for IDDQ testing. A configuration like this that permits a single external terminal (enable pad EN) to have a plurality of functions eliminates the need to separately provide a dedicated external terminal that is used only when IDDQ testing is executed, and this helps shrink the mounting area of the semiconductor device 500.

<Overview>

To follow is an overview of the various embodiments described herein.

For example, according to what is disclosed herein, a semiconductor device includes: an internal power supply configured to generate an internal supply voltage from an input voltage; a first circuit block configured to operate by being supplied with the internal supply voltage; a second circuit block configured to operate by being supplied with a node voltage appearing at an internal node; and a switcher configured to switch the connection destination of the internal node. The switcher includes: a first switch connected between an application terminal for the internal supply voltage and the internal node; and a second switch connected between an external terminal and the internal node. The second circuit block includes a switch controller configured to control the first and second switches individually. The switch controller controls the switcher such that the switching of the operating state of the switcher between a first state where the first switch is on and the second switch is off and a second state where the first switch is off and the second switch is on proceeds via a third state where the first and second switches are both on. (A first configuration.)

In the semiconductor device of the first configuration described above, the internal power supply may only have a capacity to feed a current to the application terminal for the internal power supply. (A second configuration.)

In the semiconductor device of the first or second configuration described above, the second circuit block may include a load circuit that requires different driving voltages in different operating modes. (A third configuration.)

In the semiconductor device of the third configuration described above, the load circuit may be a memory that requires different driving voltages during a data writing period and during a data non-writing period, and the switch controller may keep the switcher in the first state during the data non-writing period and in the second state during the data writing period. (A fourth configuration.)

In the semiconductor device of the first or second configuration described above, the second circuit block may be a digital circuit block that is a target on which to execute quiescent supply current testing, and the switch controller may keep the switcher in the first state during a non-execution period of the quiescent supply current testing and in the second state during an execution period of the quiescent supply current testing. (A fifth configuration.)

In the semiconductor device of the fifth configuration described above, the second switch is an N-channel MOSFET. (A sixth configuration.)

The semiconductor device of any of the first to sixth configurations described above may further include a resistor for limiting the current passing from the external terminal to a third circuit block. (A seventh configuration.)

The semiconductor device of the seventh configuration described above may further include a clamper for limiting the voltage applied from the external terminal to the third circuit block downstream of the resistor. (An eighth configuration.)

The semiconductor device of any of the first to eighth configurations described above may be enabled and disabled according to an enable signal fed to the external terminal when the switcher is in the first state. (A ninth configuration.)

For example, according to another aspect of what is disclosed herein, a voltage application method of applying an external supply voltage to the external terminal provided in the semiconductor device according to any of the first to ninth configurations described above includes: a step of setting the external supply voltage to a first voltage equal to or higher than a target voltage of the internal supply voltage before a switch from the first state to the third state; a step of raising the external supply voltage from the first voltage to a second voltage after a switch from the third state to the second state; a step of dropping the external supply voltage from the second voltage to the first voltage before a switch from the second state to the third state; and a step of stopping application of the external supply voltage after the a switch from the second state to the third state. (A tenth configuration.)

According to the invention disclosed herein, it is possible to provide a semiconductor device that permits a single terminal to have a plurality of functions.

### MODIFICATIONS

The various technical features disclosed herein may be implemented in any manners other than as in the embodiments described above, and allow for many modifications without departure from the spirit of their technical ingenuity. That is, the embodiments described above should be understood to be in every aspect illustrative and not restrictive, and the technical scope of the present invention is defined not by the description of the embodiments given above but by the appended claims and encompasses any modifications within a scope and sense equivalent to those claims.

1. A semiconductor device, comprising:
an internal power supply configured to generate an internal supply voltage from an input voltage;
a first circuit block configured to operate by being supplied with the internal supply voltage;
a second circuit block configured to operate by being supplied with a node voltage appearing at an internal node; and
a switcher configured to switch a connection destination of the internal node,
wherein
the switcher includes:
a first switch connected between an application terminal for the internal supply voltage and the internal node; and
a second switch connected between an external terminal and the internal node,
the second circuit block includes a switch controller configured to control the first and second switches individually,
the switch controller controls the switcher such that switching of an operating state of the switcher between a first state where the first switch is on and the second switch is off and a second state where the first switch is off and the second switch is on proceeds via a third state where the first and second switches are both on.

2. The semiconductor device according to claim 1, wherein
the internal power supply only has a capacity to feed a current to the application terminal for the internal power supply.

3. The semiconductor device according to claim 1, wherein
the second circuit block includes a load circuit that requires different driving voltages in different operating modes.

4. The semiconductor device according to claim 3, wherein
the load circuit is a memory that requires different driving voltages during a data writing period and during a data non-writing period, and
the switch controller keeps the switcher
in the first state during the data non-writing period and
in the second state during the data writing period.

5. The semiconductor device according to claim 1, wherein
the second circuit block is a digital circuit block that is a target on which to execute quiescent supply current testing, and
the switch controller keeps the switcher
in the first state during a non-execution period of the quiescent supply current testing and
in the second state during an execution period of the quiescent supply current testing.

6. The semiconductor device according to claim 5, wherein
the second switch is an N-channel MOSFET.

7. The semiconductor device according to claim 1, further comprising a resistor for limiting a current passing from the external terminal to a third circuit block.

8. The semiconductor device according to claim 7, further comprising a clamper for limiting a voltage applied from the external terminal to the third circuit block downstream of the resistor.

9. The semiconductor device according to claim 1, wherein
the semiconductor device is enabled and disabled according to an enable signal fed to the external terminal when the switcher is in the first state.

10. A voltage application method of applying an external supply voltage to the external terminal provided in the semiconductor device according to claim 1, the method comprising:
a step of setting the external supply voltage to a first voltage equal to or higher than a target voltage of the internal supply voltage before a switch from the first state to the third state;
a step of raising the external supply voltage from the first voltage to a second voltage after a switch from the third state to the second state;
a step of dropping the external supply voltage from the second voltage to the first voltage before a switch from the second state to the third state; and
a step of stopping application of the external supply voltage after the a switch from the second state to the third state.
